(19) United States
(12) Patent Application Publication
(10) Pub. No.: US 2026/0020171 A1
(43) Pub. Date: Jan. 15, 2026

(54) CONTROLLER CABINET GUARD APPARATUS

(71) Applicant: JCS Innovations LLC, Las Vegas, NV (US)

(72) Inventors: John MAYORGA, Las Vegas, NV (US); Rujake GROSS, Caliente, NV (US)

(21) Appl. No.: 19/097,946

(22) Filed: Apr. 2, 2025

Related U.S. Application Data
(60) Provisional application No. 63/671,396, filed on Jul. 15, 2024.
(60) Provisional application No. 63/756,612, filed on Feb. 10, 2025.

(51) Int. Cl. H05K 5/02; H05K 5/03

(52) U.S. Cl. CPC H05K 5/0221; H05K 5/03

(57) ABSTRACT

A guard apparatus is provided for protecting a controller cabinet. The guard apparatus includes a frame portion configured to overlie at least left and right side walls of the controller cabinet. At least one door portion is connectable to the frame portion and is configured to overlie at least one of a front or rear segment of the controller cabinet. The frame portion includes at least one first lock component. The door portion includes at least one second lock component configured to be aligned with the first lock component when the door portion is positioned in alignment with the frame portion to secure the door portion to the frame portion.

### CROSS-REFERENCE TO RELATED APPLICATIONS

This utility patent application claims the benefit of and priority to U.S. Provisional Patent Application Ser. No. 63/671,396, filed on Jul. 15, 2024 and U.S. Provisional Patent Application Ser. No. 63/756,612, filed on Feb. 10, 2025, both titled “Controller Cabinet Guard Apparatus,” the entire disclosures of which are hereby incorporated by reference in their entireties.

### FIELD OF THE DISCLOSURE

The present disclosure relates to controller cabinets for housing electronic equipment, such as electronic components of traffic lights.

### BACKGROUND

Controller cabinets play a crucial role in housing and safeguarding electronic equipment used in utilities. For example, they are often employed to enclose the electronic components of traffic lights, such as power distribution units, microcontrollers, communication modules, and monitoring systems. These cabinets are typically made from durable materials to protect the electronics from environmental factors. However, despite having basic locking mechanisms, they are frequently targeted by vandals and thieves.

### SUMMARY

According to an aspect of the disclosure, a guard apparatus is provided for protecting a controller cabinet. The guard apparatus includes a frame portion configured to overlie at least left and right side walls of the controller cabinet. At least one door portion is connectable to the frame portion and is configured to overlie at least one of a front or rear segment of the controller cabinet. The frame portion includes at least one first lock component. The door portion includes at least one second lock component configured to be aligned with the first lock component when the door portion is positioned in alignment with the frame portion to secure the door portion to the frame portion.

According to another aspect of the disclosure, a guard apparatus is provided for protecting a controller cabinet. The guard apparatus includes a frame portion that is configured to overlie at least left and right side walls of the controller cabinet. At least one door portion is connectable to the frame portion and is configured to overlie at least one of a front or rear segment of the controller cabinet. At least one of the frame portion and the door portion defines at least one slot. At least one of the frame portion and the door portion define at least one pin configured to be received in the at least one slot for securing the door portion to the frame portion when the door portion is positioned in alignment with the frame portion to secure the door portion to the frame portion.

According to another aspect of the disclosure, a controller cabinet assembly includes a controller cabinet with a front segment, a rear segment opposite the front segment, a left side wall, a right side wall, a top wall and a bottom wall. The controller cabinet assembly also includes a guard apparatus for protecting the controller cabinet. The guard apparatus has a frame portion that is configured to overlie at least the left and right side walls of the controller cabinet. The guard apparatus also includes at least one door portion that is connectable to the frame portion and is configured to overlie at least one of the front or rear segments of the controller cabinet. The frame portion includes at least one first lock component. The door portion includes at least one second lock component that is configured to be aligned with the first lock component when the door portion is positioned in alignment with the frame portion to secure the door portion to the frame portion.

According to these and other aspects of the disclosure, the guard apparatus prevents theft and tampering with the controller cabinet by providing a cage-like barrier around the controller cabinet which is only removable by authorized users. The guard apparatus has a simple arrangement which is inexpensive to fabricate, install and use.

### BRIEF DESCRIPTION OF THE DRAWINGS

Other aspects of the present disclosure will be readily appreciated, as the same becomes better understood by reference to the following detailed description when considered in connection with the accompanying drawings wherein:

FIG. 1 is a perspective view of a first embodiment of a guard apparatus for protecting a controller cabinet;

FIG. 1A is a magnified view of an arrangement of a pin of a door portion and a slot of a frame portion of the first embodiment of the guard apparatus;

FIG. 2 is a perspective view of the first embodiment of the guard apparatus coupled to an example controller cabinet;

FIG. 3 is a perspective, exploded view of the first embodiment of the guard apparatus;

FIG. 4 is a side view of the first embodiment of the guard apparatus;

FIG. 5 is a top view of the first embodiment of the guard apparatus;

FIG. 6 is a front view of the first embodiment of the guard apparatus;

FIG. 7 is a perspective view of a first lock component of a frame portion and a second lock component of a door portion of the first embodiment of the guard apparatus, illustrating the first and second lock components out of alignment prior to positioning the door portion in a secured position relative to the frame portion;

FIG. 8 is a perspective view of the first lock component of the frame portion and the second lock component of the door portion of the first embodiment of the guard apparatus in alignment with another after positioning the door portion in the secured position relative to the frame portion;

FIG. 9 illustrates a circular lock positioned between the first and second lock components of the first embodiment of the guard apparatus to lock the door and frame portions to one another.

FIG. 10 is a left side, perspective view of a second embodiment of a guard apparatus for protecting a controller cabinet;

FIG. 11 is a right side, perspective view of the second embodiment of the guard apparatus;

FIG. 12 is a perspective view of the second embodiment of the guard apparatus coupled to an example controller cabinet;

FIG. 13 is a perspective, exploded view of the second embodiment of the guard apparatus;

FIG. 14 is a top view of the second embodiment of the guard apparatus;

FIG. 15 is a front view of the second embodiment of the guard apparatus;

FIG. 16 is a side view of the second embodiment of the guard apparatus; and

FIG. 17 is a perspective view of an alternate arrangement of a pin of a door portion and a slot of a frame portion of the guard apparatus.

### DESCRIPTION OF EMBODIMENTS

Referring to the figures, wherein like numerals indicate corresponding parts throughout the several views, embodiments of a guard apparatus 10, 110 for protecting controller cabinets 12, 112 to prevent vandalism and tampering with the controller cabinet 12, 112 are shown. The guard apparatus 10, 110 may be used in conjunction with various types of controller cabinets 12, 112, such as those used to house electronic components of traffic lights, such as power distribution units, microcontrollers, communication modules, and monitoring mechanisms.

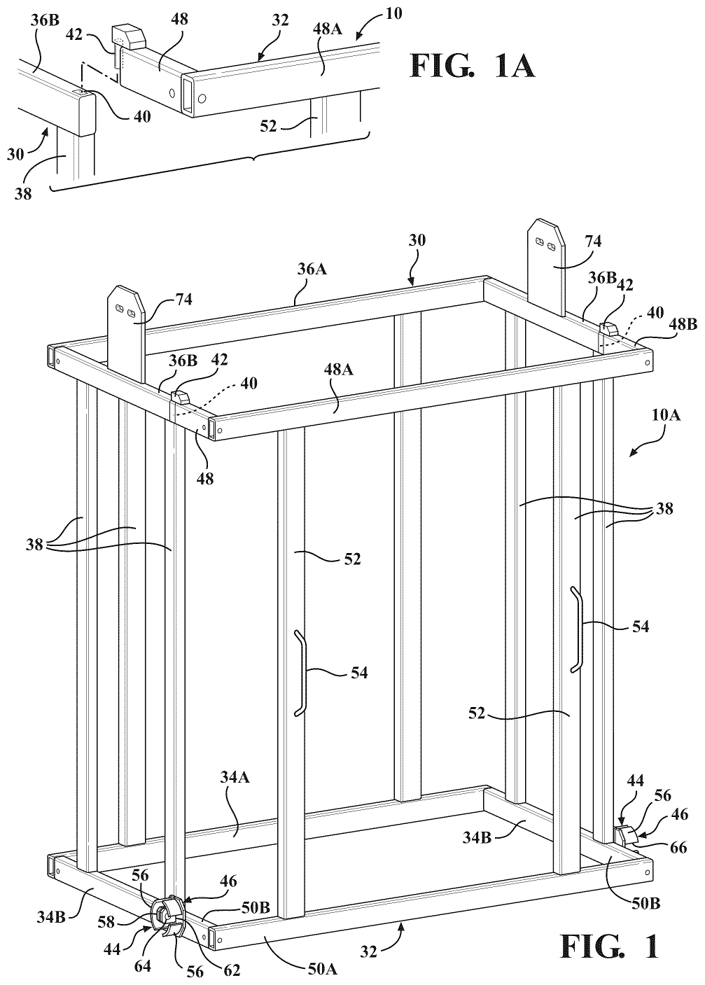

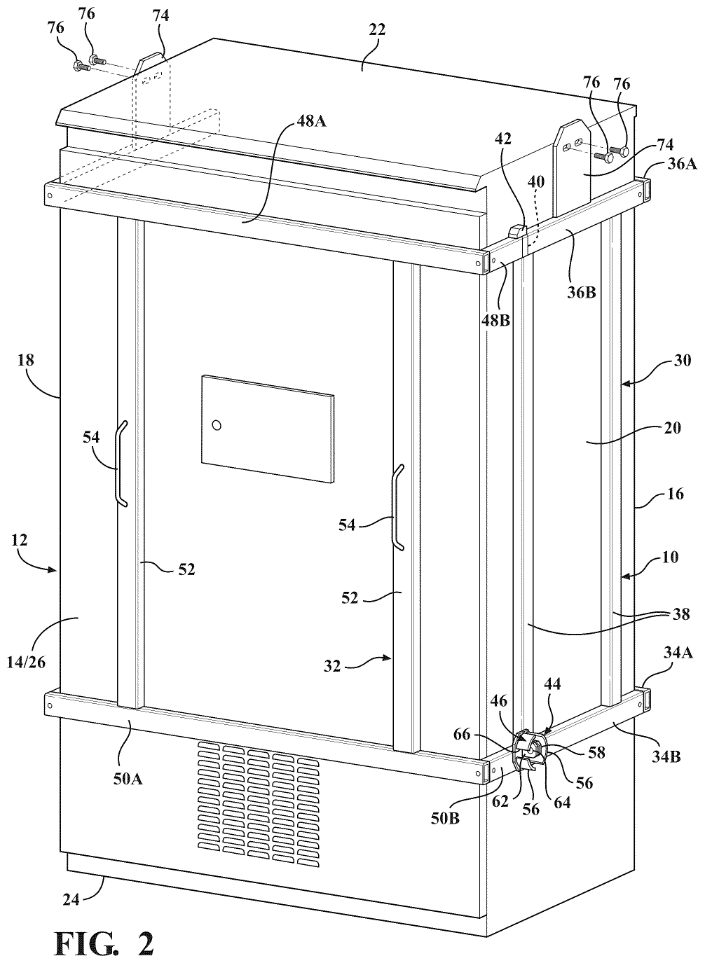

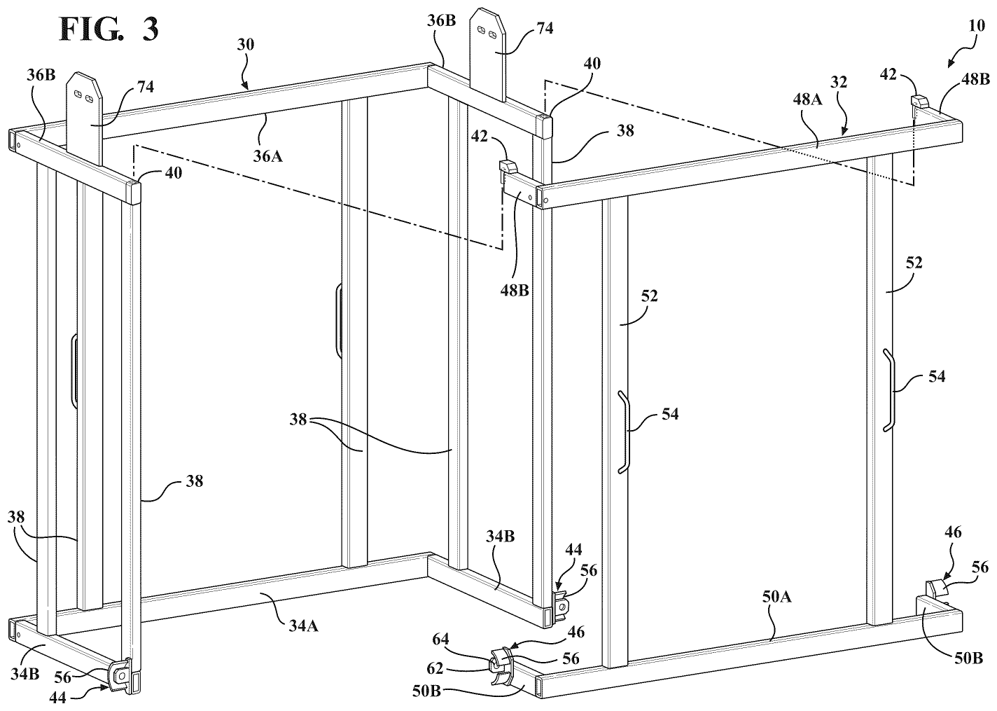

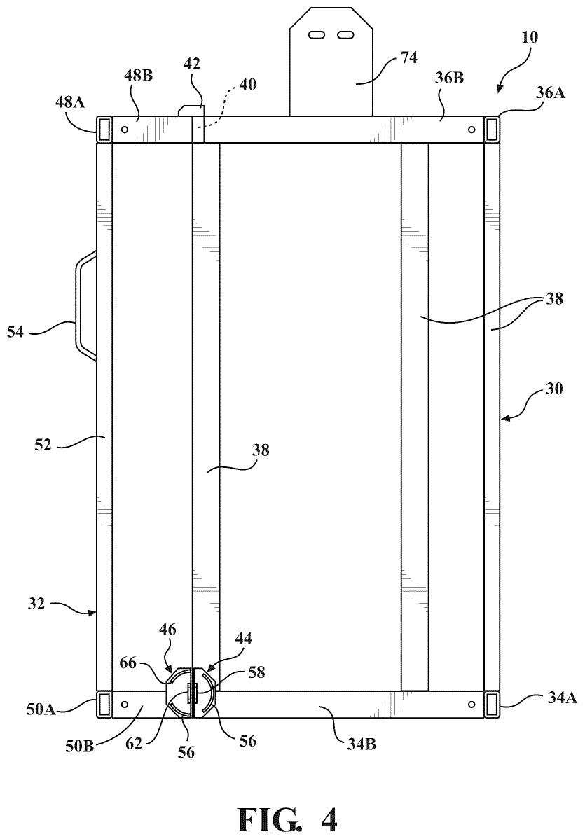

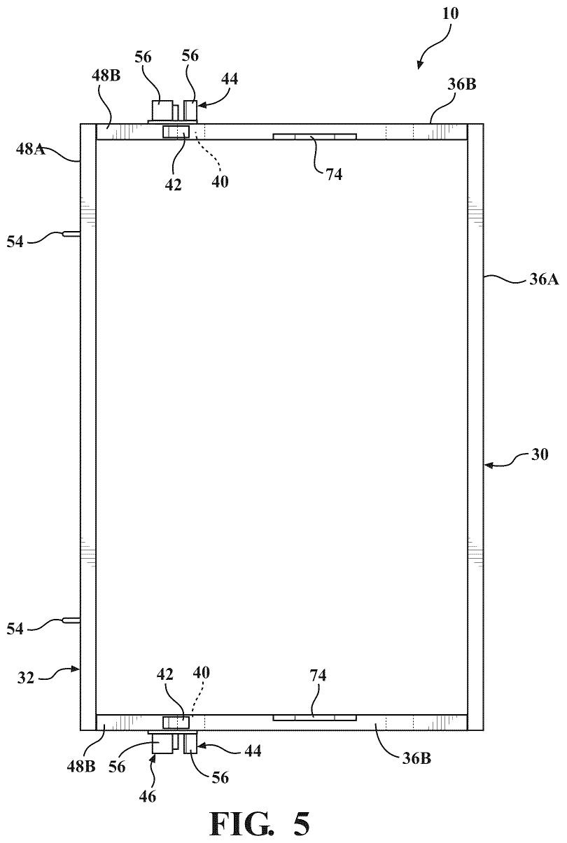

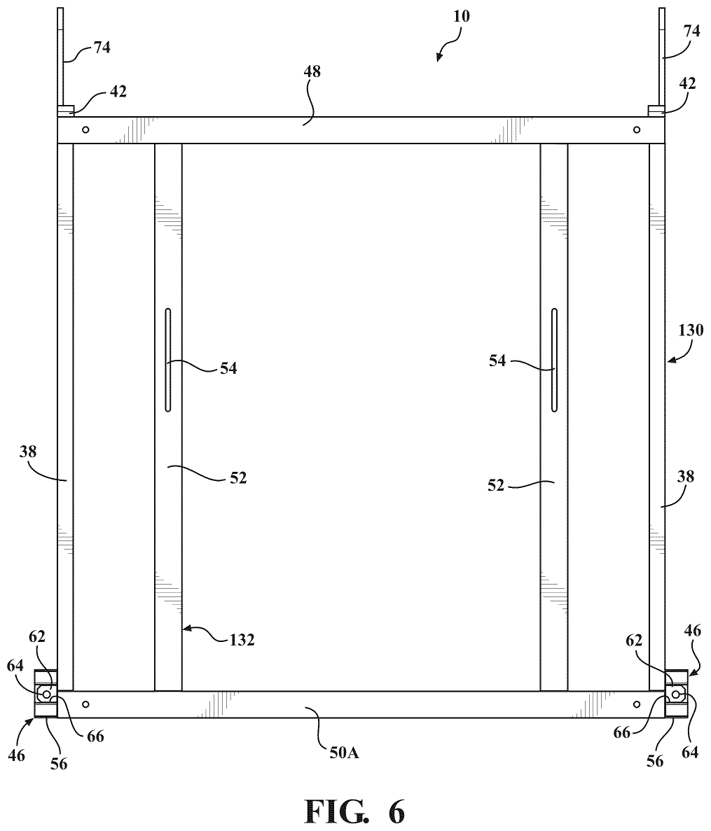

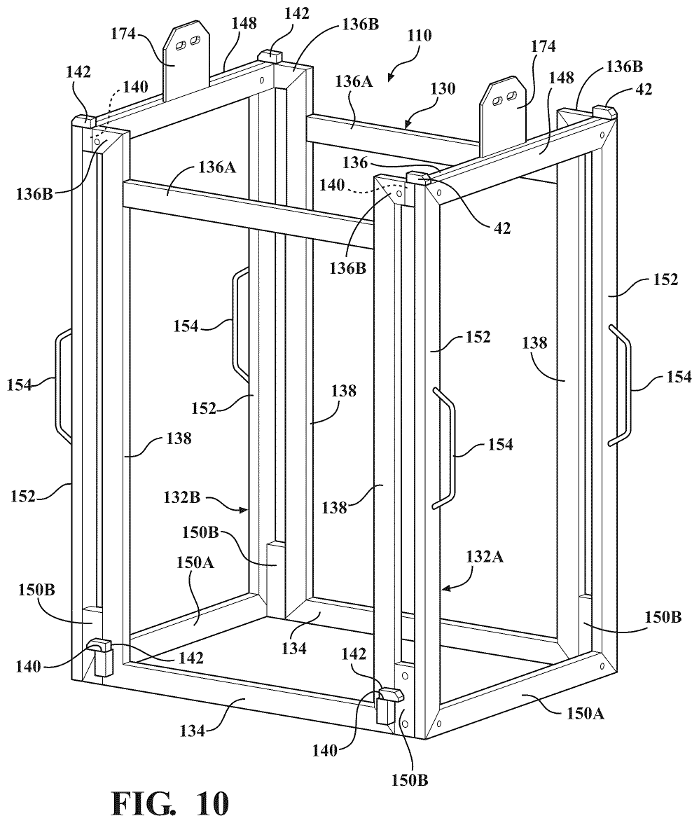

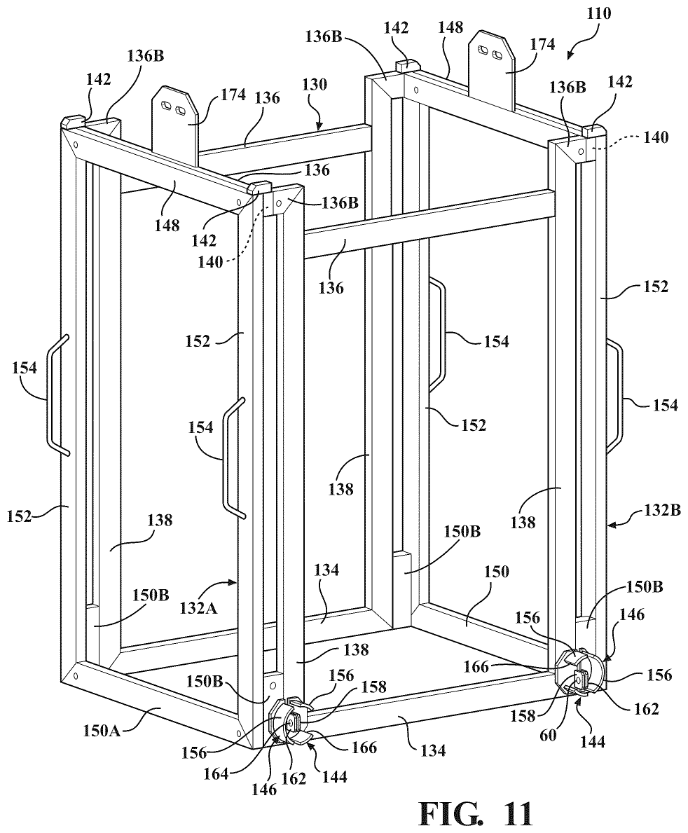

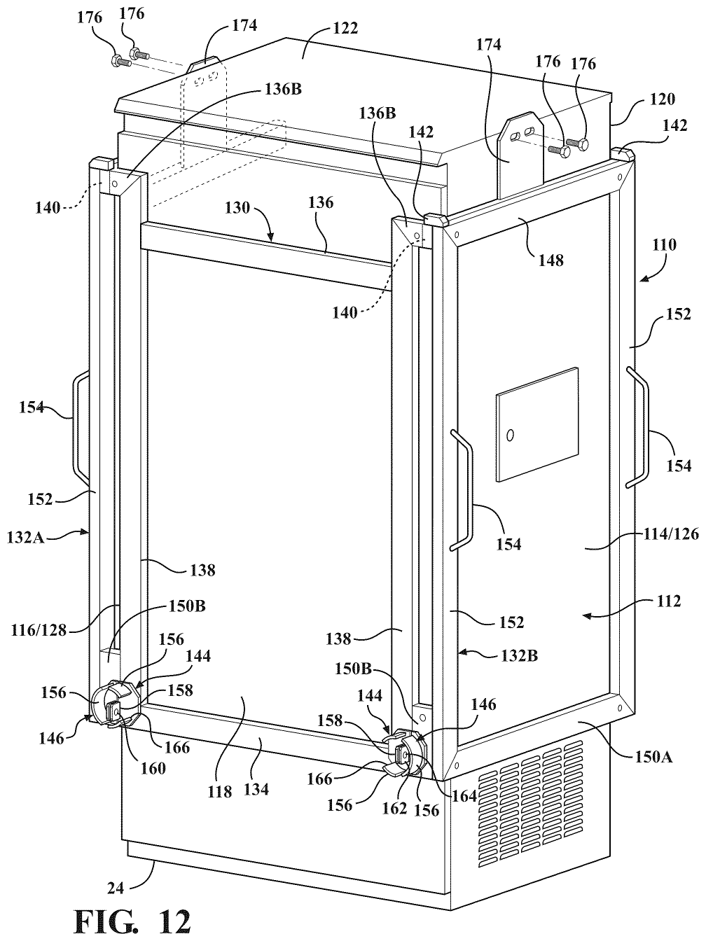

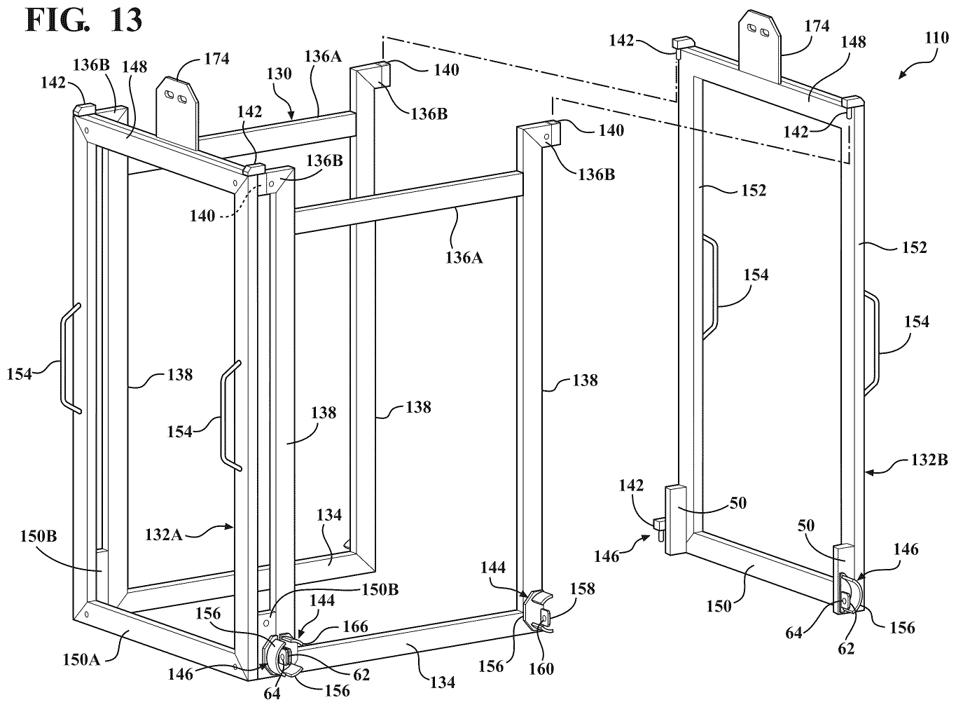

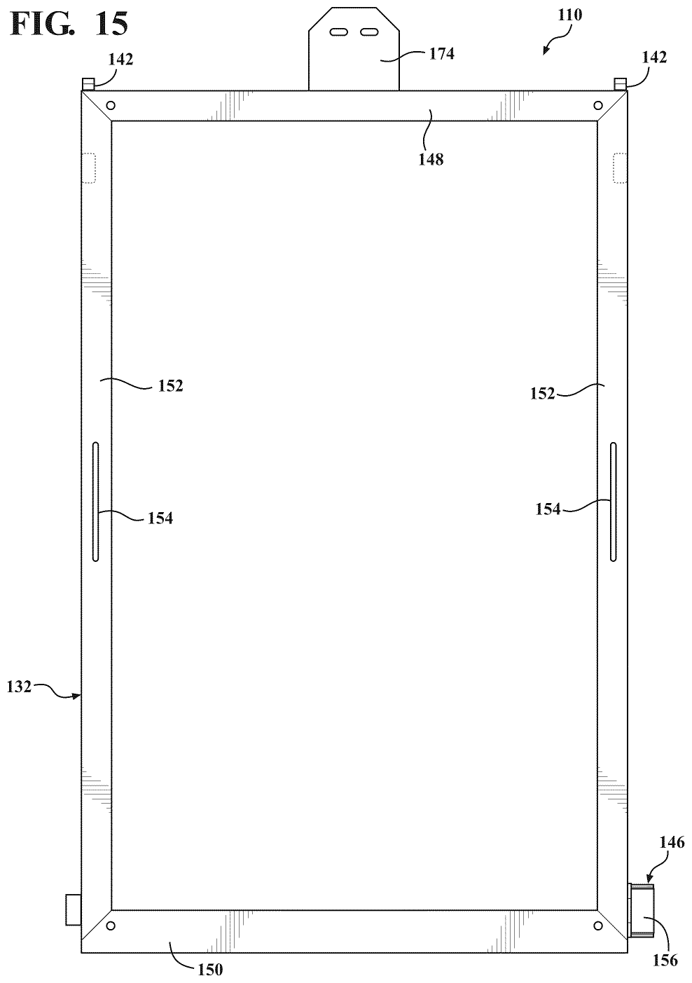

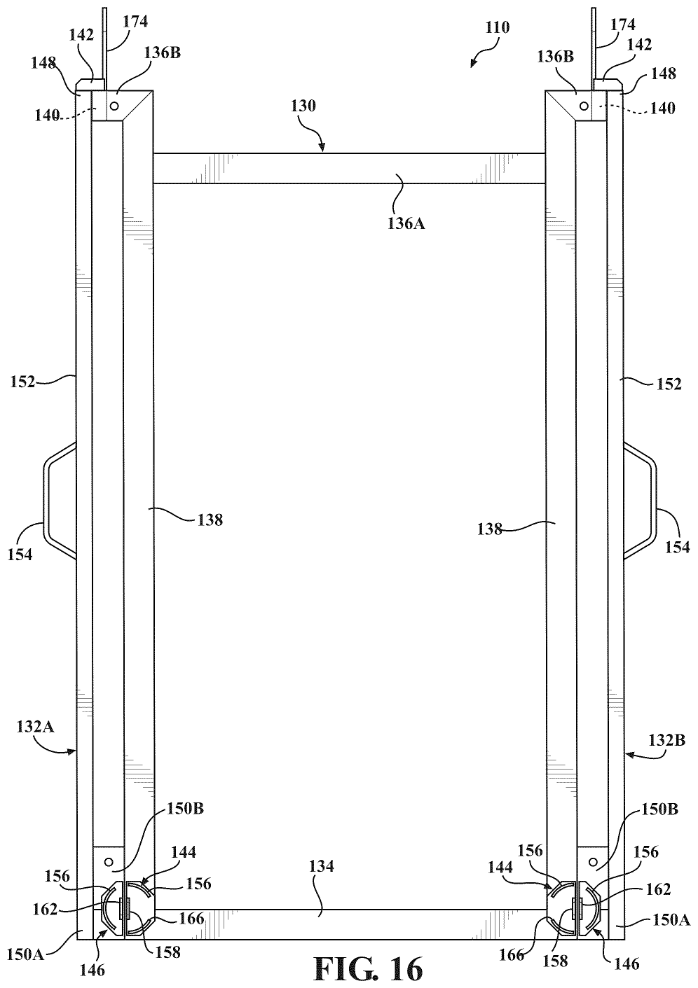

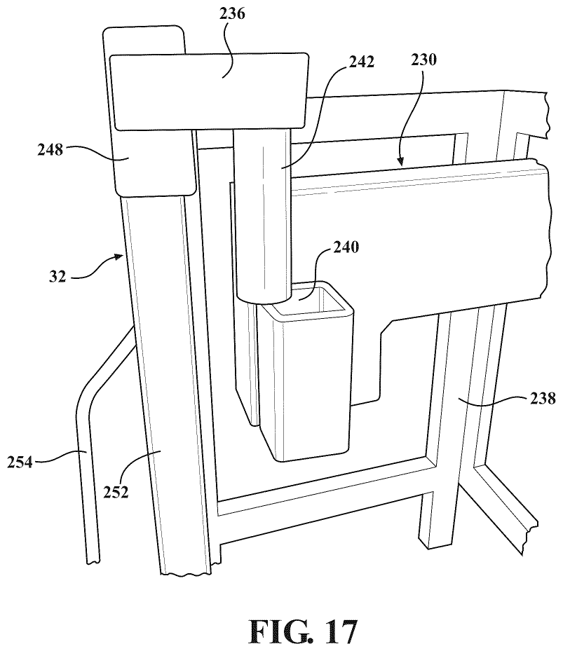

As shown in FIGS. 2 and 12, the controller cabinet 12, 112 typically has a front segment 14, 114, a rear segment 16, 116 opposite the front segment 14, 114, a left side wall 18, 118, a right side wall 20, 120, a top wall 22, 122 and a bottom wall 24, 124. A first embodiment of the guard apparatus 10 shown in FIGS. 1-9 is configured to be connected to a single door 26 controller cabinet 12, where a single first door 26 is located at the front segment 14 of the cabinet 12. A second embodiment of the guard apparatus 110 shown in FIGS. 10-16 is configured to be connected to a dual door cabinet 120, where a first door 126 is located at the front segment 114 of the cabinet, and a second door 128 is located at the rear segment 116 of the cabinet 120 opposite the first door 126. All of the components of the guard apparatus 10, 110 are made of a robust metal material, such as steel, to inhibit breaking and shearing of the guard apparatus 10, 110. Furthermore, the various components of the guard apparatus 10, 110 are connected via robust joining arrangements like welds and bolts.

According to both embodiments, the guard apparatus 10, 110 includes a frame portion 30, 130 configured to be overlie at least the left and right side walls 18, 118, 20, 120 of the cabinet 12, 112. The guard apparatus 10, 110 also includes at least one door portion 32, 132A, 132B that is connectable to the frame portion 30, 130 and configured to overlie at least one of the front and rear segments 14, 114, 16, 116. According to the first embodiment, the guard apparatus 10 includes one door portion 32 for overlying the single door 26, and according to the second embodiment, the guard apparatus 110 includes two door portions 132A, 132B for overlying both the first and second doors 126, 128.

The frame portion 30, 130 includes at least two lower horizontal bars 34A, 34B, 134 configured to overlie at least the left and right side walls 18, 118, 20, 120 of the cabinet 12, 112. The frame portion 30, 130 also includes at least two upper horizontal bars 36A, 36B, 136A, 136B that are each also configured to overlie at least the left and right side walls 18, 118, 20, 120, each positioned in spaced and parallel relationship with one of the lower horizontal bars 34A, 34B, 134. The frame portion 30, 130 also includes a plurality of vertical bars 38, 138 extending between the lower and upper horizontal bars 34A, 34B, 134, 36A, 36B, 136A, 136B perpendicularly to the lower and upper horizontal bars 34A, 34B, 134, 36A, 36B, 136A, 136B.

The frame portion 30, 130 defines one or more vertical slots 40, 140 which are configured to receive pins 42, 142 of the door portion 32, 132 to align and connect the door portion 32, 132A, 132B to the frame portion 30, 130. According to embodiments, the slots 40, 140 could be on the door portion 32, 132A, 132B, while the pins 42, 142 are on the frame portion 30, 130, or slots 40, 140 and pins 42, 142 could be located on each of the door and frame portions 32, 132A, 132B, 30, 130. Any number of slots 40, 140 and corresponding pins 42, 142 may be used.

The frame portion 30, 130 has one or more first lock components 44, 144 that are configured to be aligned with one or more second lock components 46, 146 of the door portion 32, 132A, 132B. According to the provided embodiments, at least one of the first lock components 44, 144 are located adjacent to one of the ends of at least one of the lower horizontal bars 34A, 34B, 134.

The door portions 32, 132A, 132B of both embodiments each include at least one top horizontal bar 48A. 48B, 148, and at least one bottom horizontal bar 50A, 50B, 150A, 150B. A pair of upright bars 52, 152 extend between the top and bottom horizontal bars 48A, 48B, 148, 50A, 50B, 150A, 150B of the door portion 32, 132A, 132B. A pair of handles 54, 154 are each connected to one of the upright bars 52, 152 of the door portion 32, 132A, 132B for permitting authorized users to maneuver the door portion 32, 132A, 132B into connection with the frame portion 30, 130 and to remove the door portion 32, 132A, 132B from the frame portion 30, 130.

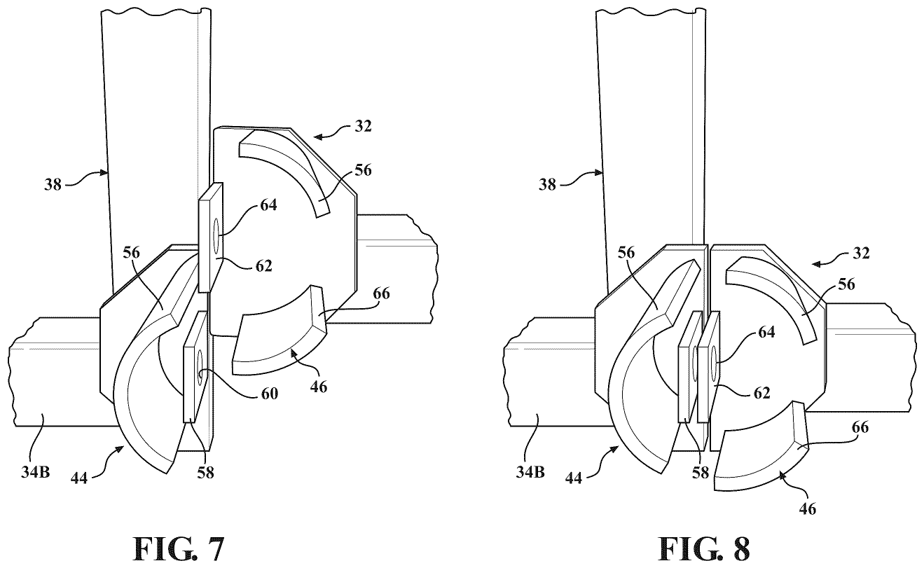

As best shown in FIGS. 7-9 and 11, according to both embodiments, the first and second circular lock components 44, 144, 46, 146 each have a semi-circular border 56, 156 such that when the first and second circular lock components 44, 144, 46, 146 are aligned with one another, the circular borders 56, 156 provide a generally circular shaped perimeter.

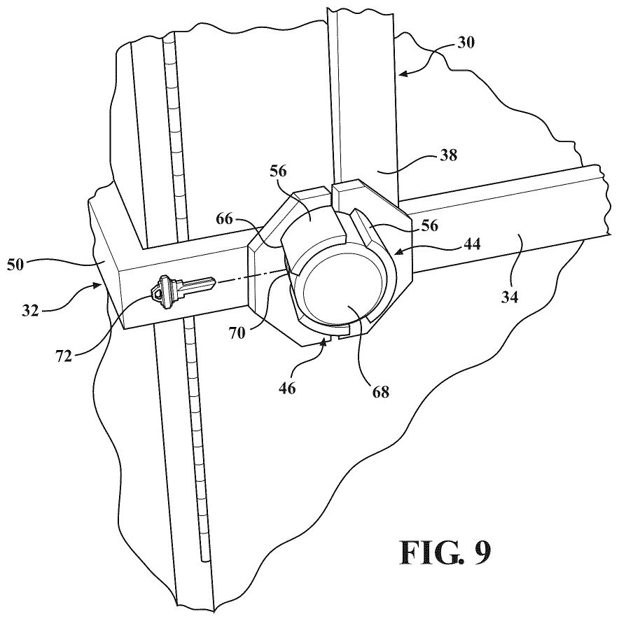

Each of the first circular lock components 44, 144 has a first vertical flange 58, 158 which defines a first orifice 60, 160. Likewise, each of the second circular lock components 46, 146 has a second vertical flange 62, 162 that defines a second orifice 64, 164. When the door portion 32, 132A, 132B is positioned in place with the pins 42, 142 of the door portion 32, 132A, 132B received in the slots 40, 140 of the frame portion 30, 130, the first and second vertical flanges 58, 158, 62, 162 and the first and second orifices 60, 160, 64, 164 are aligned with one another. Furthermore, the border 56, 156 of at least one of the first and second circular lock components 44, 144, 46, 146 defines a gap 66, 166. As shown in FIG. 9, a lock 68 is positioned centrally to the first and second lock components 44, 144, 46, 146 and includes a pin (not shown) that is configured to pass through the aligned first and second orifices 60, 160, 64, 164 to lock the first and second vertical flanges 58, 158, 62, 162 to one another. The lock 68, 168 further has a key hole 70, 170 aligned with the gap 66, 166 of the at least one of the first and second circular lock components 44, 144, 46, 146 to permit the lock 68 to be unlocked with a key 72. This provides a layer of security, as only authorized users may unlock the lock 68 to access the cabinets 12, 112.

As best shown in FIGS. 2 and 12, both embodiments include at least a pair of side flanges 74, 174 that extend upwardly from two of the upper horizontal bars 36B and/or top horizontal bars 148, each into alignment with mounting holes on the side walls 18, 118, 20, 120 of the cabinet 12, 112. One or more fasteners 76, 176 extend into orifices of the side flanges 74, 174 and the mounting holes of the cabinet 12, 112 to further secure the guard apparatus 10, 110 to the cabinet 12, 112. Any number of side flanges 74, 174 may be used, and they may instead be located toward a bottom of the guard apparatus 10, 110 for being secured to a bottom region of the cabinet 12, 112.

With specific reference to the first embodiment of the guard apparatus 10 of FIGS. 1-9, the frame portion 30 has three lower horizontal bars 34A, 34B total. One of the lower horizontal bars 34A, 34B is a rear lower horizontal bar 34A which extends between two forward lower horizontal bars 34B and is configured to overlie the rear segment 16 of the cabinet 12. The forward lower horizontal bars 34B extend perpendicularly to the rear horizontal bar 34A and overlie the side segments 18, 20 of the cabinet 12. The frame portion 30 also has three upper horizontal bars 36A, 36B. One of the upper horizontal bars 36A, 36B is a rear upper horizontal bar 36A which extends between two forward upper horizontal bars 36B and is configured to overlie the rear segment 16 of the cabinet 12. The upper horizontal bars 36B extend perpendicularly to the rear upper horizontal bar 36A and are configured to overlie the side segments 18, 20 of the cabinet 12. The two forward upper horizontal bars 36B each define one of the vertical slots 40 adjacent to ends of the forward upper horizontal bars 36B. Furthermore, a pair of the first lock components 44 are each located at ends of the two forward lower horizontal bars 34B. That frame portion 30 also has three top horizontal bars 48A, 48B of the door portion 32, with a first of the top horizontal bars 48A, 48B being a front top horizontal bar 50A configured to overlie the first door 26 between two side top horizontal bars 50B extending perpendicularly from the front top horizontal bar 48A for overlying the left and right walls 18, 20 of the cabinet 12. Furthermore, the frame portion 30 has three bottom horizontal bars 50A, 50B of the door portion 32, with a first of the bottom horizontal bars 50A, 50B being a front bottom horizontal bar 50A configured to overlie the at least one door 26 of the cabinet 12 between two side bottom horizontal bars 50B. The two side bottom horizontal bars 50B extend perpendicularly from the front bottom horizontal bar 50A for overlying the left and right walls 18, 20 of the cabinet 12. Furthermore, the pins 42 of the door portion 32 are each located at one of the ends of two of the side top horizontal bars 48B. Also, two second circular lock components 46 are each located at an end of the two side bottom horizontal bars 50B.

With specific reference to the second embodiment of guard apparatus 110 shown in FIGS. 10-16, a first door portion 132A is configured to overlie the front segment 114 of the cabinet 120 which includes a first cabinet door 126, and a second door portion 132B is configured to overlie the rear segment 116 of the cabinet 120 which includes a second cabinet door 128.

Furthermore, the upper horizontal bars 136A, 136B of the frame portion 130 include two first upper horizontal bars 136A extending parallel to one another, and four second upper horizontal bars 136B positioned above, and connected to the two first upper horizontal bars 136A. The four second upper horizontal bars 136B each extend outwardly beyond an end of the two first upper horizontal bars 136A. Furthermore, the two first upper horizontal bars 136A are each connected to, and extend perpendicularly from a top of two of the vertical bars 138. Four vertical slots 140 are each defined at an end of one of the second upper horizontal bars 136B.

The frame portion 130 includes two lower horizontal bars 134 that extend parallel to one another, each connected to and extending perpendicularly relative to two of the vertical bars 138. Two first circular lock components 144 are each located at an end of one of the lower horizontal bars 138. Each of the door portions has 132 has three bottom horizontal bars 150A, 150B, with a first of the bottom horizontal bars 150 being a sideways bottom horizontal bar 150A configured to overlie one of the cabinet doors 126, 128. Also, two of the bottom horizontal bars 150A, 150B are forward bottom horizontal bars 150B that extend perpendicularly from ends of the sideways bottom horizontal bars 150A for overlying the left and right walls 118, 120 of the cabinet 120.

Furthermore, two pins 142 are located at ends of the top horizontal bars 148 of the door portion 132 and one pin 142 is located on one of the forward bottom horizontal bars 150B. Additionally, a second lock components 146 is located at an end of one of the forward bottom horizontal bars 150B of the door portion 132.

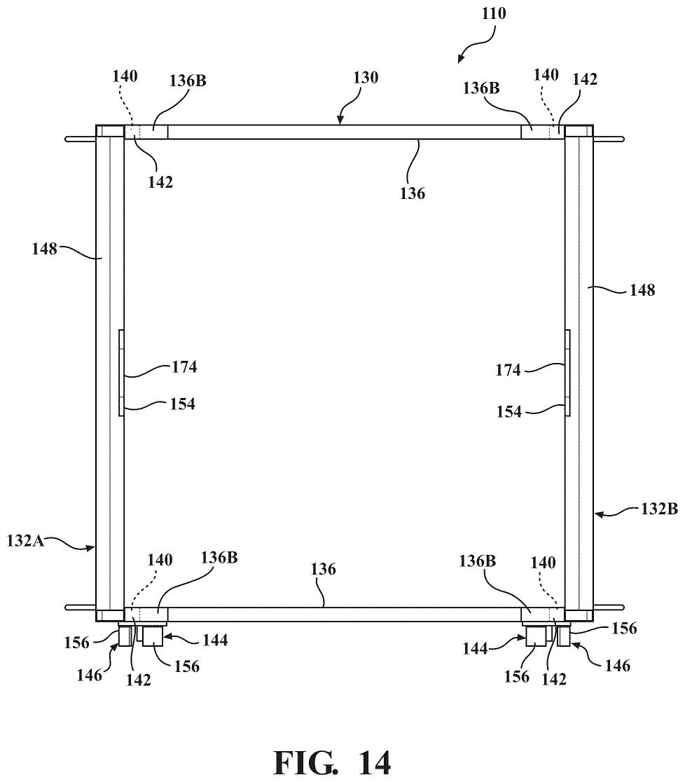

FIG. 14 shows an alternate arrangement of a pin 236 and slot 240 that may be used in conjunction with any embodiment. The pin and slot arrangement may have various shapes and sizes.

In view of the foregoing, the guard apparatus 10, 100 is securely mounted and bolted to the controller cabinet 12, 112 in a way that deters tampering or cutting through the guard apparatus 10, 100, providing a high level of security for the controller cabinet 12, 112, while also permitting access to authorized users. The guard apparatus 10, 100 reduces instances of theft and damage, ensuring the reliability and longevity of critical infrastructure stored in the controller cabinet 12, 112.

More particularly, the guard apparatus 10, 100 is designed to prevent unauthorized tampering and access to the controller cabinet 12, 120 through several protective features. The guard apparatus 10, 110 is constructed from metals with robust joints connecting components, making it highly resistant to bending and shearing. The various bars of the guard apparatus 10, 100 cover a large area of the cabinet 12, 112 in both horizontal and vertical directions, effectively blocking access to high-traffic areas like doors and access panels. Additionally, the guard apparatus 10, 100 is securely bolted to either the top or bottom of the cabinet 12, 112, providing a strong anchoring effect. The door sections 32, 132A, 132B of the frame portion 30, 130 can only be removed by unlocking the lock components 44, 144, 46, 146, allowing access to the doors 26, 126, 128 of the cabinet 12, 112 to authorized individuals.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in that particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or later, or intervening element or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to described various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in any embodiment, even if not specifically shown or described. The same may also be varied in many ways. Such variations are not to be regarded as a departure from the disclosure, and all such modifications are intended to be included within the scope of the disclosure.

What is claimed is:

1. A guard apparatus for protecting a controller cabinet, comprising:
a frame portion configured to overlie at least left and right side walls of the controller cabinet;
at least one door portion connectable to the frame portion and configured to overlie at least one of a front or rear segment of the controller cabinet;
the frame portion including at least one first lock component; and
the door portion including at least one second lock component configured to be aligned with the first lock component when the door portion is positioned in alignment with the frame portion to secure the door portion to the frame portion.

2. The guard apparatus as set forth in claim 1, wherein the frame portion includes at least two lower horizontal bars configured to overlie a lower region of the left and right side walls of the controller cabinet, and wherein the frame portion also includes two upper horizontal bars configured to overlie an upper region of the left and right side walls of the controller cabinet.

3. The guard apparatus as set forth in claim 2, wherein the frame portion further includes a plurality of vertical bars interconnecting the upper and lower horizontal bars.

4. The guard apparatus as set forth in claim 1, wherein the door portion includes at least one top horizontal bar configured to overlie an upper region of a door of the controller cabinet, and wherein the door portion includes at least one bottom horizontal bar configured to overlie a lower region of the door of the controller cabinet.

5. The guard apparatus as set forth in claim 4, wherein the door portion further includes a plurality of upright bars interconnecting the top and bottom horizontal bars.

6. The guard apparatus as set forth in claim 1, wherein at least one of the frame portion and the door portion define at least one slot, and wherein at least one of the frame portion and the door portion have at least one pin configured to be received in the at least one slot for securing the door portion to the frame portion when the door portion is positioned in alignment with the frame portion.

7. A guard apparatus for protecting a controller cabinet, comprising:
a frame portion configured to overlie at least left and right side walls of the controller cabinet;
at least one door portion connectable to the frame portion and configured to overlie at least one of a front or rear segment of the controller cabinet;
at least one of the frame portion and the door portion defining at least one slot; and
at least one of the frame portion and the door portion having at least one pin configured to be received in the at least one slot for securing the door portion to the frame portion when the door portion is positioned in alignment with the frame portion to secure the door portion to the frame portion.

8. The guard apparatus as set forth in claim 7, wherein the frame portion includes at least two lower horizontal bars configured to overlie a lower region of the left and right side walls of the controller cabinet, and wherein the frame portion also includes two upper horizontal bars configured to overlie upper regions of the left and right side walls of the controller cabinet.

9. The guard apparatus as set forth in claim 7, wherein an end of at least one of the upper horizontal bars of the frame portion defines the at least one slot.

10. The guard apparatus as set forth in claim 9, wherein the at least one pin is located at an end of at least one of the top horizontal bars.

11. The guard apparatus as set forth in claim 8, wherein the frame portion further includes a plurality of vertical bars interconnecting the upper and lower horizontal bars.

12. The guard apparatus as set forth in claim 7, wherein the door portion includes at least one top horizontal bar configured to overlie an upper region of a door of the controller cabinet, and wherein the door portion includes at least one bottom horizontal bar configured to overlie a lower region of the door of the controller cabinet.

13. The guard apparatus as set forth in claim 12, wherein the door portion further includes a plurality of upright bars interconnecting the top and bottom horizontal bars.

14. The guard apparatus as set forth in claim 7, wherein the frame portion includes at least one first lock component, and the door portion includes at least one second lock component configured to be aligned with the first lock component when the door portion is positioned in alignment with the frame portion to secure the door portion to the frame portion.

15. A controller cabinet assembly, comprising:
a controller cabinet having a front segment, a rear segment opposite the front segment, a left side wall, a right side wall, a top wall and a bottom wall;
a guard apparatus for protecting the controller cabinet:
the guard apparatus including a frame portion configured to overlie at least the left and right side walls of the controller cabinet;
the guard apparatus also including at least one door portion connectable to the frame portion and configured to overlie at least one of the front or rear segments of the controller cabinet;
the frame portion including at least one first lock component; and
the door portion including at least one second lock component configured to be aligned with the first lock component when the door portion is positioned in alignment with the frame portion to secure the door portion to the frame portion.

16. The guard apparatus as set forth in claim 15, wherein the frame portion includes at least two lower horizontal bar configured to overlie a lower region of the left and right side walls of the controller cabinet, and wherein the frame portion also includes two upper horizontal bars configured to overlie an upper region of the left and right side walls of the controller cabinet.

17. The guard apparatus as set forth in claim 16, wherein the frame portion further includes a plurality of vertical bars interconnecting the upper and lower horizontal bars.

18. The guard apparatus as set forth in claim 15, wherein the door portion includes at least one top horizontal bar configured to overlie an upper region of a door of the controller cabinet, and wherein the door portion includes at least one bottom horizontal bar configured to overlie a lower region of the door of the controller cabinet.

19. The guard apparatus as set forth in claim 18, wherein the door portion further includes a plurality of upright bars interconnecting the top and bottom horizontal bars.

20. The guard apparatus as set forth in claim 15, wherein at least one of the frame portion and the door portion define at least one slot, and wherein at least one of the frame portion and the door portion have at least one pin configured to be received in the at least one slot for securing the door portion to the frame portion when the door portion is positioned in alignment with the frame portion.
